(19) United States
(12) Patent Application Publication
(10) Pub. No.: US 2025/0386524 A1
(43) Pub. Date: Dec. 18, 2025

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Yuji KAWASAKI, Tokyo (JP); Toshihiro IMASAKA, Tokyo (JP); Manabu YOSHINO, Tokyo (JP); Takuichiro SHITOMI, Tokyo (JP)

(73) Assignee: Mitsubishi Electric Corporation, Tokyo (JP)

(21) Appl. No.: 19/094,769

(22) Filed: Mar. 28, 2025

(30) Foreign Application Priority Data
Jun. 14, 2024 (JP) 2024-096583

(51) Int. Cl. H10D 1/66; H01L 21/265; H10D 1/00; H10D 62/60

(52) U.S. Cl. CPC H10D 1/66; H10D 1/047; H10D 62/60; H01L 21/265

(57) ABSTRACT

A semiconductor device includes a first semiconductor region, a second semiconductor region, an insulating film, and a conductive film provided on the second semiconductor region with the insulating film interposed between the conductive film and the second semiconductor region, the second semiconductor region including an upper region, a middle region which is provided to be deeper than the upper region and has a higher impurity concentration than the upper region, and a lower region which is provided to be deeper than the middle region, has a lower impurity concentration than the middle region, the impurity concentration in the lower region being constant at a depth of 0.5 μm or more.

### BACKGROUND

### Technical Field

The present disclosure relates to a semiconductor device and a method of manufacturing a semiconductor device.

### Description of the Background Art

Various technologies have been proposed for a metal-oxide-semiconductor (MOS) capacitor constituting an integrated circuit (IC) such as an analog integrated circuit. For example, Japanese Patent Application Laid-Open No. H08-097363 proposes a technique capable of enhancing reliability while reducing the occupied area by increasing a concentration of an impurity diffusion region forming a MOS capacitor from an interface toward the inside of a semiconductor substrate.

When a thickness of a semiconductor region having an impurity concentration and forming the MOS capacitor is thin, a trade-off relationship between a capacitance value of the MOS capacitor and gate voltage dependence of the MOS capacitor becomes remarkable. Therefore, there is a problem that it is required to improve the trade-off relationship between the capacitance value of the MOS capacitor and the gate voltage dependence of the MOS capacitor when the thickness of the semiconductor region having the impurity concentration is relatively thin.

### SUMMARY

The present disclosure has been made in view of the above problem, and an object thereof is to provide a technique capable of improving a trade-off relationship when a thickness of a semiconductor region having an impurity concentration is relatively thin.

A semiconductor device according to the present disclosure includes: a first semiconductor region; a second semiconductor region provided on the first semiconductor region, at least a part of the second semiconductor region having an impurity concentration higher than an impurity concentration of the first semiconductor region; an insulating film provided on the second semiconductor region; and a conductive film provided on the second semiconductor region with the insulating film interposed between the conductive film and the second semiconductor region, the second semiconductor region including an upper region, a middle region which is provided to be deeper than the upper region and has a higher impurity concentration than the upper region, and a lower region which is provided to be deeper than the middle region and has a lower impurity concentration than the middle region, the impurity concentration in the lower region being constant at a depth of 0.5 μm or more.

When the thickness of the second semiconductor region is relatively thin, the trade-off relationship between the capacitance value of the MOS capacitor and the gate voltage dependence of the MOS capacitor can be improved.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view illustrating a configuration of a MOS capacitor according to a first preferred embodiment;

FIG. 2 is a view illustrating a relationship between a capacitance value of a MOS capacitor and a gate voltage;

FIG. 3 is a view illustrating a concentration profile of a second semiconductor region of the MOS capacitor according to the first preferred embodiment;

FIG. 4 is a view illustrating a relationship between the capacitance value and gate voltage dependence of a MOS capacitor;

FIG. 5 is a view illustrating a concentration profile of a second semiconductor region of a MOS capacitor according to a second preferred embodiment;

FIG. 6 is a view illustrating a relationship between a capacitance value and gate voltage dependence of the MOS capacitor;

FIG. 7 is a view illustrating a concentration profile of a second semiconductor region of a MOS capacitor according to a third preferred embodiment;

FIG. 8 is a view illustrating a concentration profile of a second semiconductor region of a MOS capacitor according to a fourth preferred embodiment;

FIG. 9 is a view illustrating a concentration profile of a second semiconductor region of a MOS capacitor according to a fifth preferred embodiment;

FIG. 10 is a cross-sectional view illustrating a configuration of a MOS capacitor according to a seventh preferred embodiment; and

FIG. 11 is a view illustrating a concentration profile of a second semiconductor region of the MOS capacitor according to the seventh preferred embodiment.

### DESCRIPTION OF THE PREFERRED EMBODIMENTS

Hereinafter, preferred embodiments will be described with reference to the accompanying drawings. Features described in the following preferred embodiments are examples, and all the features are not necessarily essential. In the following description, similar constituent elements in a plurality of preferred embodiments are denoted by the same or similar reference numerals, and different constituent elements will be mainly described. In the following description, specific positions and directions such as “upper”, “lower”, “left”, “right”, “front”, and “back” do not necessarily coincide with actual positions and directions in practice. In addition, the fact that a certain portion has a higher concentration than another portion may mean that, for example, an average concentration of the certain portion is higher than an average concentration of another portion. Conversely, the fact that a certain portion has a lower concentration than another portion may mean that, for example, an average concentration of the certain portion is lower than an average concentration of another portion.

### First Preferred Embodiment

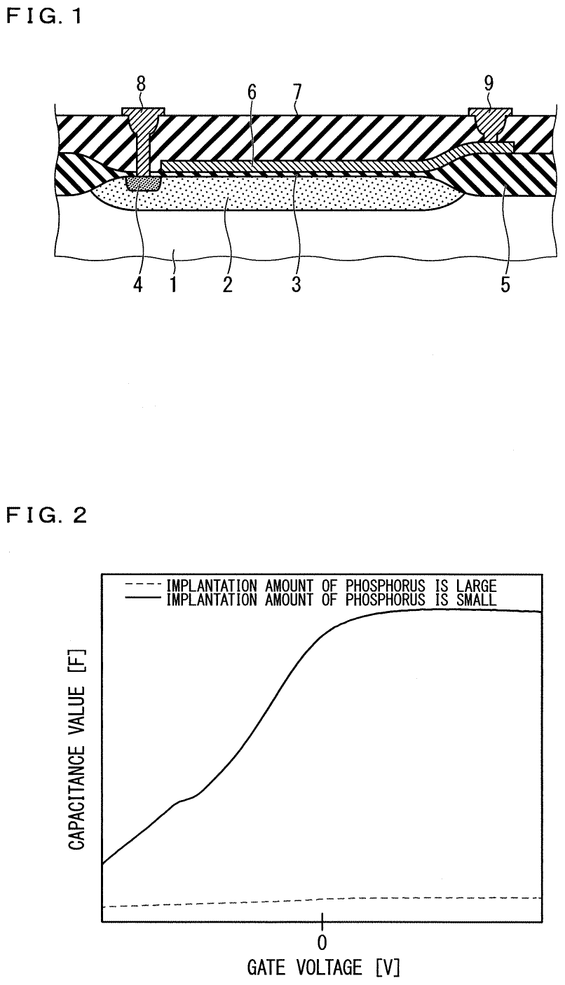

FIG. 1 is a cross-sectional view illustrating a configuration of a MOS capacitor which is a semiconductor device according to a first preferred embodiment. The MOS capacitor of FIG. 1 includes a first semiconductor region 1, a second semiconductor region 2, a gate insulating film 3 which is an insulating film, a third semiconductor region 4, a field insulating film 5, a conductive film 6, an interlayer insulating film 7, a back gate electrode 8, and a gate electrode 9.

The first semiconductor region 1, the second semiconductor region 2, and the third semiconductor region 4 are provided in a semiconductor layer. The semiconductor layer may include a normal semiconductor wafer or may include an epitaxial growth layer. The semiconductor layer may be made of normal silicon (Si), or may be made of a wide bandgap semiconductor such as silicon carbide (SiC), gallium nitride (GaN), gallium oxide (Ga₂O₃), or diamond. In a case where the semiconductor layer is made of a wide bandgap semiconductor, stable operation under a high temperature and a high voltage, a high switching speed, and the like can be expected. Hereinafter, a configuration in which conductivity types of the first semiconductor region 1, the second semiconductor region 2, and the third semiconductor region 4 are N-type will be mainly described, but the conductivity types may be P-type.

The second semiconductor region 2 is selectively provided on the first semiconductor region 1 by, for example, implantation of impurities. An N-type impurity concentration of at least a part of the second semiconductor region 2 is higher than an N-type impurity concentration of the first semiconductor region 1. Although FIG. 1 illustrates a boundary line between the first semiconductor region 1 and the second semiconductor region 2, the N-type impurity concentrations of the first semiconductor region 1 and the second semiconductor region 2 near the boundary line may be the same.

The third semiconductor region 4 is selectively provided on the second semiconductor region 2 by, for example, implantation of impurities. An N-type impurity concentration of at least a part of the third semiconductor region 4 is higher than the N-type impurity concentration of the second semiconductor region 2. Although FIG. 1 illustrates a boundary line between the second semiconductor region 2 and the third semiconductor region 4, the N-type impurity concentrations of the second semiconductor region 2 and the third semiconductor region 4 near the boundary line may be the same.

The gate insulating film 3 is provided on the second semiconductor region 2. In FIG. 1, the gate insulating film 3 is provided continuously with the field insulating film 5 configured to electrically separate elements. The gate insulating film 3 and the field insulating film 5 are formed by, for example, thermal oxidation, but are not limited thereto. The field insulating film 5 is thicker than the gate insulating film 3, and an interface between the second semiconductor region 2 and the gate insulating film 3 is located on the upper side of an interface between the first semiconductor region 1 and the field insulating film 5.

The conductive film 6 is provided on a portion of the second semiconductor region 2 where the third semiconductor region 4 is not provided with the gate insulating film 3 interposed therebetween. A part of the conductive film 6 is provided on the field insulating film 5. A material of the conductive film 6 is, for example, polysilicon, but is not limited thereto.

The interlayer insulating film 7 is provided on the field insulating film 5 and the conductive film 6. The back gate electrode 8 is connected to the third semiconductor region 4 via a contact hole of the interlayer insulating film 7, and the third semiconductor region 4 reduces a contact resistance value between the back gate electrode 8 and the second semiconductor region 2. The gate electrode 9 is connected to the conductive film 6 on the field insulating film 5 via another contact hole of the interlayer insulating film 7. Hereinafter, a configuration in which a gate voltage is appropriately applied to the gate electrode 9 and a potential of the back gate electrode 8 is a reference potential will be described as an example, but the present invention is not limited thereto.

In a case where a positive gate voltage is applied to the gate electrode 9, positive charges are accumulated in the conductive film 6, and negative charges are accumulated on a surface of the N-type second semiconductor region 2. In this state, a depletion layer is hardly formed in the second semiconductor region 2, so that a capacitance value C of the MOS capacitor is substantially equal to a gate insulating film capacitance value Cox.

On the other hand, in a case where a negative gate voltage is applied to the gate electrode 9, negative charges are accumulated in the conductive film 6, and a depletion layer is formed on the surface of the N-type second semiconductor region 2. Since a depletion layer width of the depletion layer varies depending on the negative gate voltage, a depletion layer capacitance value Cd of such a portion varies depending on the negative gate voltage. The depletion layer capacitance value Cd and the gate insulating film capacitance value Cox are connected in series, and the capacitance value C (combined capacitance value C) of the MOS capacitor is expressed by the following Formula (1).

$$C = ( 1 / ( 1 / Cox + 1 / Cd ) \qquad ( 1 )$$

As an absolute value of the negative gate voltage increases, the spread of the depletion layer increases, and the depletion layer capacitance value Cd decreases. As a result, influence of the depletion layer capacitance value Cd on the combined capacitance value C increases, gate voltage dependence of the combined capacitance value C increases. Although it is sufficient to increase the impurity concentration of the second semiconductor region 2 in order to suppress the spread of the depletion layer, if the impurity concentration is increased, for example, accelerated oxidation of silicon proceeds due to thermal oxidation during formation of the gate insulating film 3 to be processed in a later step, and a thickness tox of the gate insulating film 3 becomes extremely large. If the thickness tox increases, the gate insulating film capacitance value Cox decreases, which causes a problem that the combined capacitance value C decreases.

FIG. 2 is a view illustrating a relationship between the capacitance value C (combined capacitance value C) of the MOS capacitor and the gate voltage when the N-type second semiconductor region 2 is formed under two implantation conditions with different implantation amounts of phosphorus. When the implantation amount of phosphorus is reduced, a surface concentration of the second semiconductor region 2 decreases, the accelerated oxidation during the thermal oxidation is suppressed, the thickness tox of the gate insulating film 3 decreases, and the gate insulating film capacitance value Cox increases. Therefore, in a case where the implantation amount of phosphorus is small (a solid line in FIG. 2), the combined capacitance value C can be made larger than that in a case where the implantation amount of phosphorus is large (a dotted line in FIG. 2).

However, if the concentration of phosphorus in the second semiconductor region 2 decreases, the depletion layer spreads as the absolute value of the negative gate voltage increases, and the depletion layer capacitance value Cd decreases. As a result, the influence of the depletion layer capacitance value Cd on the combined capacitance value C when the gate voltage is the negative voltage increases, and the gate voltage dependence of the combined capacitance value C increases as indicated by the solid line in FIG. 2.

As described above, there is a trade-off relationship between the capacitance value C of the MOS capacitor and the gate voltage dependence of the MOS capacitor regarding the magnitude of the impurity concentration in a region from the outermost surface of the second semiconductor region 2 to a depth at which the depletion layer spreads. In order to improve this trade-off relationship, for example, it is conceivable to increase the impurity concentration to stabilize the gate voltage dependence, and compensate for a decrease in the capacitance value of the MOS capacitor by increasing the area of the MOS capacitor. However, in this case, there arises a new problem that the area of an integrated circuit increases.

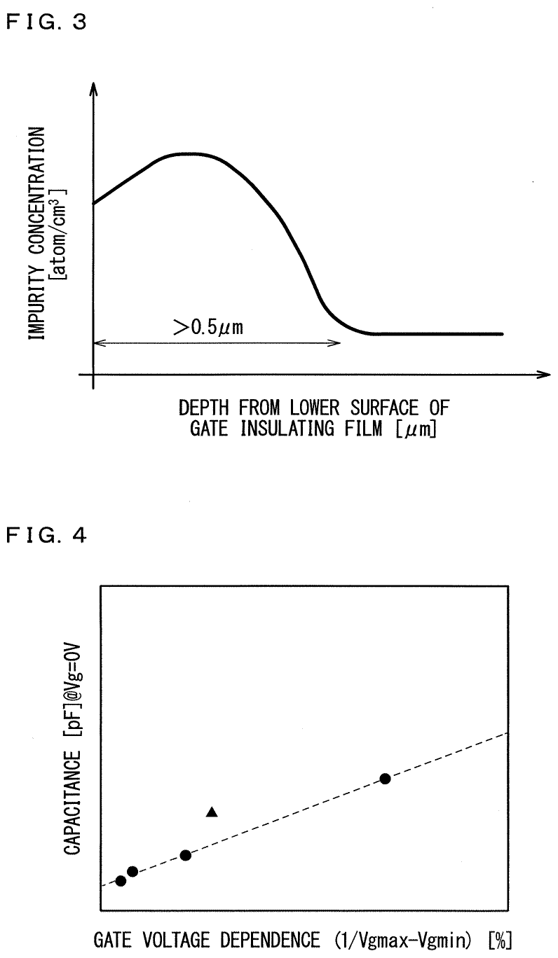

Therefore, in the MOS capacitor according to the first preferred embodiment, an appropriate concentration profile of the second semiconductor region 2 is obtained in order to improve the trade-off relationship. FIG. 3 is a view illustrating the concentration profile of the second semiconductor region 2 according to the first preferred embodiment.

The second semiconductor region 2 includes an upper region (a left region in FIG. 3), a middle region (a middle region in FIG. 3), and a lower region (a right region in FIG. 3). The middle region is provided to be deeper than the upper region, and the impurity concentration in the middle region is higher than the impurity concentration in the upper region. The lower region is provided to be deeper than the middle region, the impurity concentration in the lower region is lower than the impurity concentration in the middle region, and the impurity concentration in the lower region is constant at a depth of 0.5 μm or more. Here, the fact that the impurity concentration is constant means that, for example, a local change in the impurity concentration is about 10% or less of the impurity concentration.

According to the MOS capacitor according to the first preferred embodiment as described above, since the impurity concentration in the upper region close to the gate insulating film 3 is lower than the impurity concentration in the middle region, the accelerated oxidation can be suppressed. As a result, the gate insulating film capacitance value Cox can be increased, so that the capacitance value C of the MOS capacitor can be increased. Meanwhile, the impurity concentration of the entire second semiconductor region 2 can be increased by the impurity concentration in the middle region, and the spread of the depletion layer can be suppressed, so that the gate voltage dependence of the MOS capacitor can be suppressed. Therefore, the trade-off relationship between the capacitance value of the MOS capacitor and the gate voltage dependence of the MOS capacitor can be improved. Note that the concentration of the second semiconductor region 2 is preferably the highest in a portion where the depletion layer is formed.

In the first preferred embodiment, the impurity concentration in the lower region is constant at the depth of 0.5 μm or more. According to such a configuration, the trade-off relationship can be improved in a configuration in which the thickness of the second semiconductor region 2 is relatively thin, that is, in a configuration in which the trade-off relationship between the capacitance value of the MOS capacitor and the gate voltage dependence of the MOS capacitor is particularly remarkable.

### Second Preferred Embodiment

A cross-sectional view illustrating a configuration of a MOS capacitor which is a semiconductor device according to a second preferred embodiment is similar to the cross-sectional view of FIG. 1.

FIG. 4 is a view illustrating a relationship between a capacitance value of the MOS capacitor and gate voltage dependence. A straight line in FIG. 4 is a straight line obtained by plotting and connecting values obtained when an impurity concentration (phosphorus concentration) of the second semiconductor region 2 having the entirely uniform impurity concentration is changed. The trade-off relationship described in the first preferred embodiment is established on this straight line.

The improvement of the trade-off relationship described in the first preferred embodiment corresponds to proceeding in the upper left direction in FIG. 4. A triangular point in FIG. 4 is a point obtained by plotting a value obtained in a case where an implantation acceleration energy is higher than an implantation acceleration energy used in the MOS capacitors in which the values on the straight line in FIG. 4 are obtained. The triangular point in FIG. 4 is located substantially on the upper left side of the straight line, and from this result, it is found that the trade-off relationship can be improved by increasing the implantation acceleration energy. The reason for the improvement is considered to be that accelerated oxidation can be suppressed as impurities are more easily implanted into a middle region than an upper region of the second semiconductor region 2 by increasing the implantation acceleration energy.

In consideration of the above, in a method of manufacturing the MOS capacitor according to the second preferred embodiment, the second semiconductor region 2 is formed by implantation of impurities using an implantation acceleration energy with a projected range of 0.2 μm or more and 0.3 μm or less. In the second preferred embodiment, the MOS capacitor is manufactured such that a concentration profile of the second semiconductor region 2 is predominantly determined during formation of the gate insulating film 3. The fact that the concentration profile of the second semiconductor region 2 is predominantly determined during the formation of the gate insulating film 3 means that the concentration profile of the second semiconductor region 2 at the time of heat treatment included in processing of forming the gate insulating film 3 is substantially the same as the concentration profile when the MOS capacitor is completed. For example, in a case where the manufacturing process is performed at a temperature lower than that of the heat treatment after the heat treatment included in the processing of forming the gate insulating film 3 to complete the MOS capacitor, the concentration profile of the second semiconductor region 2 is predominantly determined during the formation of the gate insulating film 3.

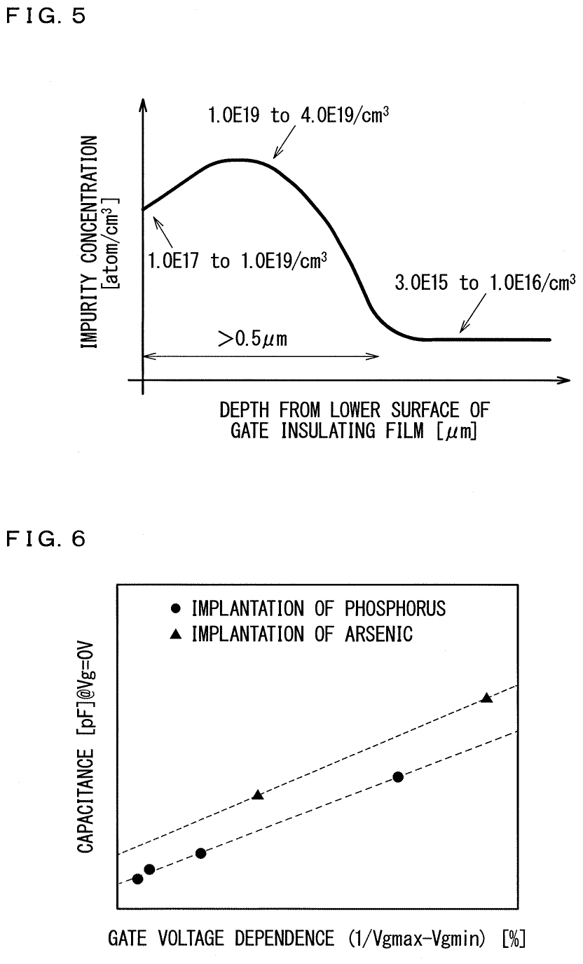

FIG. 5 is a view illustrating a concentration profile of the second semiconductor region 2 of the MOS capacitor manufactured by the manufacturing method according to the second preferred embodiment. The impurity concentration in an upper portion of the upper region is 1.0E17/cm³ or more and 1.0E19/cm³ or less. The impurity concentration in the middle region has a peak higher than 1.0E19/cm³ and lower than 4.0E19/cm³ at a depth of 0.2 μm or more and 0.3 μm or less from a lower surface of the gate insulating film 3. The impurity concentration in a lower region is 3.0E15/cm³ or more and less than 1.0E16/cm³ at a depth of 0.5 μm or more from the lower surface of the gate insulating film 3. With such a configuration, the trade-off relationship between the capacitance value of the MOS capacitor and the gate voltage dependence of the MOS capacitor can be improved as in the first preferred embodiment.

### Third Preferred Embodiment

A cross-sectional view illustrating a configuration of a MOS capacitor which is a semiconductor device according to a third preferred embodiment is similar to the cross-sectional view of FIG. 1.

FIG. 6 is a view illustrating a relationship between a capacitance value of the MOS capacitor and gate voltage dependence. Straight lines in FIG. 6 are straight lines obtained by plotting and connecting values obtained when an impurity concentration of the second semiconductor region 2 having the entirely uniform impurity concentration is changed. The trade-off relationship described in the first preferred embodiment is also established on the straight lines.

The improvement of the trade-off relationship described in the first preferred embodiment corresponds to proceeding in the upper left direction in FIG. 6. Impurities in the straight line on the lower right side in FIG. 6 is phosphorus, and impurities in the straight line on the upper left side are arsenic. From this result, it is found that formation of the second semiconductor region 2 by implantation of arsenic, which is an impurity having a smaller diffusion coefficient than phosphorus, can improve the trade-off relationship more as compared with phosphorus.

The reason for the improvement is considered to be that the diffusion of arsenic by heat treatment after the implantation is less likely to occur than the diffusion of phosphorus, and thus, arsenic is less likely to reach an upper region of the second semiconductor region 2, and accelerated oxidation can be suppressed. Although not illustrated, in a case where a conductivity type of the second semiconductor region 2 is p-type, formation of the second semiconductor region 2 by implantation of BF₂, which is an impurity having a smaller diffusion coefficient than boron, can improve the trade-off relationship more as compared with boron.

In consideration of the above, in a method of manufacturing the MOS capacitor according to the third preferred embodiment, the second semiconductor region 2 is formed by implantation of impurities having a smaller diffusion coefficient than phosphorus or boron. In the third preferred embodiment, the MOS capacitor is manufactured such that a concentration profile of the second semiconductor region 2 is predominantly determined during formation of the gate insulating film 3 as in the second preferred embodiment.

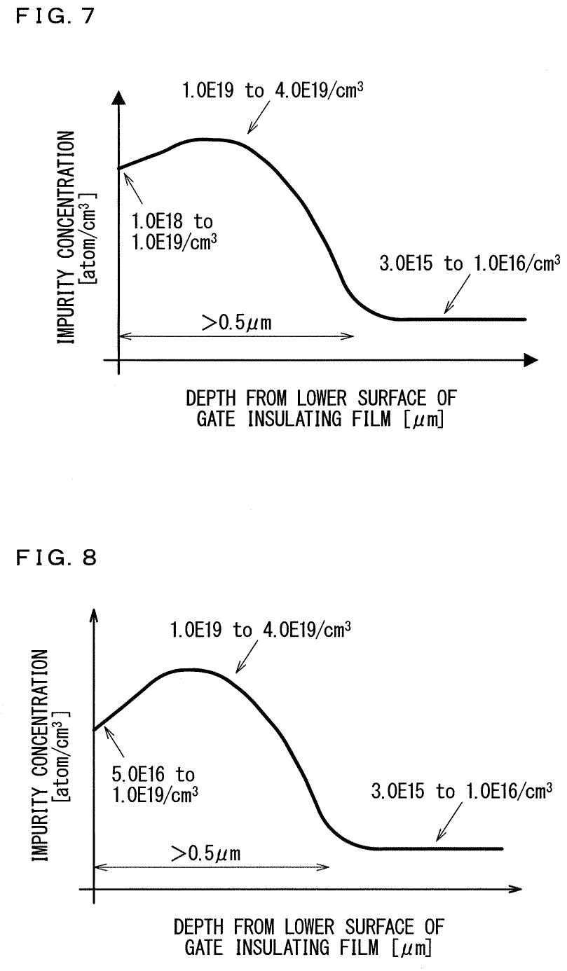

FIG. 7 is a view illustrating the concentration profile of the second semiconductor region 2 of the MOS capacitor manufactured by the manufacturing method according to the third preferred embodiment. The impurity concentration in an upper portion of the upper region is 1.0E18/cm³ or more and 1.0E19/cm³ or less. The impurity concentration in a middle region has a peak higher than 1.0E19/cm³ and lower than 4.0E19/cm³ at a depth of 0.2 μm or more and 0.3 μm or less from a lower surface of the gate insulating film 3. The impurity concentration in a lower region is 3.0E15/cm³ or more and less than 1.0E16/cm³ at a depth of 0.5 μm or more from the lower surface of the gate insulating film 3. With such a configuration, the trade-off relationship between the capacitance value of the MOS capacitor and the gate voltage dependence of the MOS capacitor can be improved as in the first preferred embodiment.

### Fourth Preferred Embodiment

A cross-sectional view illustrating a configuration of a MOS capacitor which is a semiconductor device according to a fourth preferred embodiment is similar to the cross-sectional view of FIG. 1.

A manufacturing method according to the fourth preferred embodiment includes the manufacturing method according to the second preferred embodiment and the manufacturing method according to the third preferred embodiment. That is, in the method of manufacturing the MOS capacitor according to the fourth preferred embodiment, the second semiconductor region 2 is formed by implantation of impurities having a smaller diffusion coefficient than phosphorus or boron an using implantation acceleration energy with a projected range of 0.2 μm or more and 0.3 μm or less. In the fourth preferred embodiment, the MOS capacitor is manufactured such that a concentration profile of the second semiconductor region 2 is predominantly determined during formation of the gate insulating film 3 as in the second preferred embodiment.

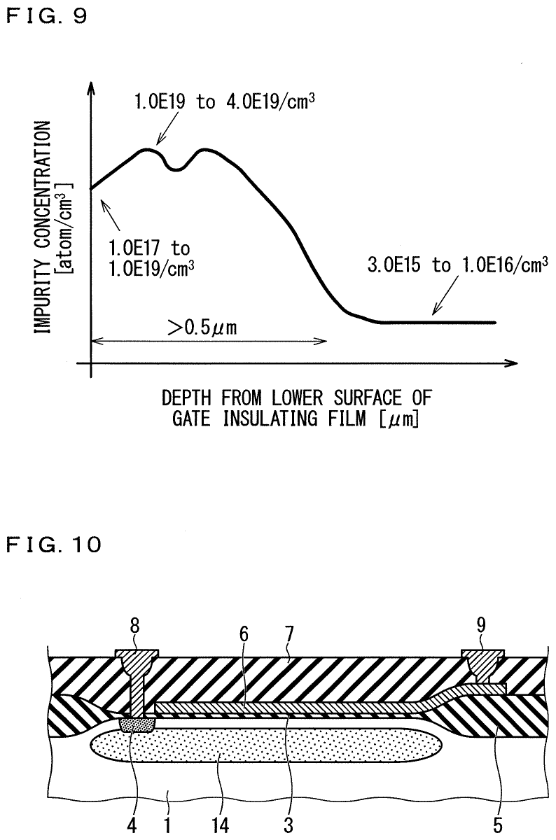

FIG. 8 is a view illustrating the concentration profile of the second semiconductor region 2 of the MOS capacitor manufactured by the manufacturing method according to the third preferred embodiment. An impurity concentration in an upper portion of an upper region is 5.0E16/cm³ or more and 1.0E19/cm³ or less. The impurity concentration in a middle region has a peak higher than 1.0E19/cm³ and lower than 4.0E19/cm³ at a depth of 0.2 μm or more and 0.3 μm or less from a lower surface of the gate insulating film 3. The impurity concentration in a lower region is 3.0E15/cm³ or more and less than 1.0E16/cm³ at a depth of 0.5 μm or more from the lower surface of the gate insulating film 3. With such a configuration, a trade-off relationship between a capacitance value of the MOS capacitor and gate voltage dependence of the MOS capacitor can be improved as in the first preferred embodiment.

### Fifth Preferred Embodiment

A cross-sectional view illustrating a configuration of a MOS capacitor which is a semiconductor device according to a fifth preferred embodiment is similar to the cross-sectional view of FIG. 1.

In a method of manufacturing the MOS capacitor according to the fifth preferred embodiment, the second semiconductor region 2 is formed by implantation of impurities using different implantation acceleration energies with a projected range of 0.2 μm or more and 0.3 μm or less. In the fifth preferred embodiment, the MOS capacitor is manufactured such that a concentration profile of the second semiconductor region 2 is predominantly determined during formation of the gate insulating film 3 as in the second preferred embodiment.

FIG. 9 is a view illustrating the concentration profile of the second semiconductor region 2 of the MOS capacitor manufactured by the manufacturing method according to the fifth preferred embodiment. An impurity concentration in an upper portion of an upper region is 1.0E17/cm³ or more and 1.0E19/cm³ or less. The impurity concentration in a middle region has a plurality of peaks higher than 1.0E19/cm³ and lower than 4.0E19/cm³ at a depth of 0.05 μm or more and less than 0.5 μm from a lower surface of the gate insulating film 3. The impurity concentration in a lower region is 3.0E15/cm³ or more and less than 1.0E16/cm³ at a depth of 0.5 μm or more from the lower surface of the gate insulating film 3.

With such a configuration, the impurity concentration can be made higher in a relatively deep portion of the second semiconductor region 2 as compared with the first preferred embodiment. As a result, since the spread of a depletion layer can be suppressed and gate voltage dependence can be reduced, a trade-off relationship between a capacitance value of the MOS capacitor and the gate voltage dependence of the MOS capacitor can be further improved.

### Sixth Preferred Embodiment

A cross-sectional view illustrating a configuration of a MOS capacitor which is a semiconductor device according to a sixth preferred embodiment is similar to the cross-sectional view of FIG. 1.

Implantation of impurities of different conductivity types into the same portion can substantially offset an impurity concentration. Using this fact, in a method of manufacturing the MOS capacitor according to the sixth preferred embodiment, the second semiconductor region 2 is formed by implantation of impurities of different conductivity types using an implantation acceleration energy with a projected range of 0.2 μm or more and 0.3 μm or less. For example, after an n-type concentration profile having one peak as illustrated in FIG. 5 is formed, p-type impurities are locally implanted into a middle region to form a concentration profile having a plurality of peaks as illustrated in FIG. 9.

If impurities to be implanted are different, the projected range varies even with the same implantation acceleration energy. Therefore, the implantation acceleration energy may be changed for each of the impurities to be implanted, or may be constant regardless of the impurities to be implanted. In the sixth preferred embodiment, the MOS capacitor is manufactured such that a concentration profile of the second semiconductor region 2 is predominantly determined during formation of the gate insulating film 3 as in the second preferred embodiment.

According to the sixth preferred embodiment as described above, since the concentration profile similar to that of the fifth preferred embodiment can be formed, a trade-off relationship between a capacitance value of the MOS capacitor and gate voltage dependence of the MOS capacitor can be improved as in the fifth preferred embodiment.

### Seventh Preferred Embodiment

FIG. 10 is a cross-sectional view illustrating a configuration of a MOS capacitor which is a semiconductor device according to a seventh preferred embodiment. In the seventh preferred embodiment, the gate insulating film 3 is provided on the second semiconductor region 14 with the first semiconductor region 1 interposed therebetween. The third semiconductor region 4 is also partially provided in the first semiconductor region 1 on the second semiconductor region 14.

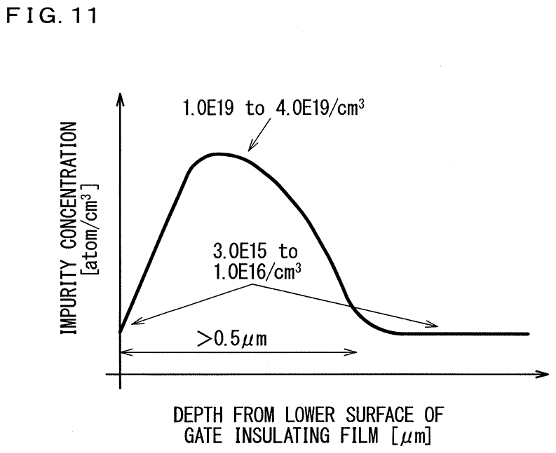

FIG. 11 is a view illustrating a concentration profile of the second semiconductor region 14 of the MOS capacitor according to the seventh preferred embodiment.

An impurity concentration of the first semiconductor region 1 is 3.0E15/cm³ or more and less than 1.0E16/cm³. An impurity concentration in an upper portion of an upper region of the second semiconductor region 14 is equal to or higher than the impurity concentration of the first semiconductor region 1. The impurity concentration in a middle region has a peak higher than 1.0E19/cm³ and lower than 4.0E19/cm³ at a depth of 0.2 μm or more and 0.3 μm or less from a lower surface of the gate insulating film 3. The impurity concentration in a lower region is 3.0E15/cm³ or more and less than 1.0E16/cm³ at a depth of 0.5 μm or more from the lower surface of the gate insulating film 3.

According to the seventh preferred embodiment as described above, since a capacitance value of the MOS capacitor can be increased by further suppressing accelerated oxidation, a trade-off relationship between the capacitance value of the MOS capacitor and gate voltage dependence of the MOS capacitor can be further improved.

In the present disclosure in English, ‘a’ and ‘an’ mean one or more. Therefore, ‘a’, ‘an’, ‘one or more’ and ‘at least one’ can be used in the same meaning.

Note that each of the preferred embodiments and each of the modifications can be freely combined, and each of the preferred embodiments and each of the modifications can be appropriately modified or omitted.

Hereinafter, various aspects of the present disclosure will be collectively described as appendices.

### Appendix 1

A semiconductor device comprising:
a first semiconductor region;
a second semiconductor region provided on the first semiconductor region, at least a part of the second semiconductor region having an impurity concentration higher than an impurity concentration of the first semiconductor region;
an insulating film provided on the second semiconductor region; and
a conductive film provided on the second semiconductor region with the insulating film interposed between the conductive film and the second semiconductor region,
the second semiconductor region including
an upper region,
a middle region which is provided to be deeper than the upper region and has the impurity concentration higher than the impurity concentration in the upper region, and
a lower region which is provided to be deeper than the middle region, has the impurity concentration lower than the impurity concentration in the middle region, the impurity concentration in the lower region being constant at a depth of 0.5 μm or more.

### Appendix 2

The semiconductor device according to Appendix 1, wherein
the impurity concentration in an upper portion of the upper region is 1.0E17/cm³ or more and 1.0E19/cm³ or less,
the impurity concentration in the middle region has a peak higher than 1.0E19/cm³ at a depth of 0.2 μm or more and 0.3 μm or less from a lower surface of the insulating film, and
the impurity concentration in the lower region is less than 1.0E16/cm³ at a depth of 0.5 μm or more from the lower surface of the insulating film.

### Appendix 3

The semiconductor device according to Appendix 1 or 2, wherein
the impurity concentration in an upper portion of the upper region is 1.0E18/cm³ or more and 1.0E19/cm³ or less,
the impurity concentration in the middle region has a peak higher than 1.0E19/cm³ at a depth of 0.2 μm or more and 0.3 μm or less from a lower surface of the insulating film, and
the impurity concentration in the lower region is less than 1.0E16/cm³ at a depth of 0.5 μm or more from the lower surface of the insulating film.

### Appendix 4

The semiconductor device according to Appendix 1 or 2, wherein
the impurity concentration in an upper portion of the upper region is 1.0E17/cm³ or more and 1.0E19/cm³ or less,
the impurity concentration in the middle region has a plurality of peaks higher than 1.0E19/cm³ at a depth of 0.05 μm or more and less than 0.5 μm from a lower surface of the insulating film, and
the impurity concentration in the lower region is less than 1.0E16/cm³ at a depth of 0.5 μm or more from the lower surface of the insulating film.

### Appendix 5

The semiconductor device according to any one of Appendices 1 to 4, wherein
the insulating film is provided on the second semiconductor region with the first semiconductor region interposed between the insulating film and the second semiconductor region, the first semiconductor region having the impurity concentration of less than 1.0E16/cm³.
the impurity concentration in an upper portion of the upper region is equal to or higher than the impurity concentration of the first semiconductor region,
the impurity concentration in the middle region has a peak higher than 1.0E19/cm³ at a depth of 0.2 μm or more and 0.3 μm or less from a lower surface of the insulating film, and
the impurity concentration in the lower region is less than 1.0E16/cm³ at a depth of 0.5 μm or more from the lower surface of the insulating film.

### Appendix 6

A method of manufacturing the semiconductor device according to Appendix 1 or 2, the method comprising forming the second semiconductor region by implantation of an impurity using an implantation acceleration energy with a projected range of 0.2 μm or more and 0.3 μm or less,
wherein a profile of the second semiconductor region is predominantly determined during formation of the insulating film.

### Appendix 7

A method of manufacturing the semiconductor device according to Appendix 1 or 3, the method comprising forming the second semiconductor region by implantation of an impurity having a smaller diffusion coefficient than phosphorus or boron,
wherein a profile of the second semiconductor region is predominantly determined during formation of the insulating film.

### Appendix 8

A method of manufacturing the semiconductor device according to Appendix 1, the method comprising forming the second semiconductor region by implantation of an impurity having a smaller diffusion coefficient than phosphorus or boron using an implantation acceleration energy with a projected range of 0.2 μm or more and 0.3 μm or less,
wherein a profile of the second semiconductor region is predominantly determined during formation of the insulating film.

### Appendix 9

A method of manufacturing the semiconductor device according to Appendix 1 or 4, the method comprising forming the second semiconductor region by implantation of an impurity using different implantation acceleration energies with a projected range of 0.2 μm or more and 0.3 μm or less,
wherein a profile of the second semiconductor region is predominantly determined during formation of the insulating film.

### Appendix 10

A method of manufacturing the semiconductor device according to Appendix 1 or 4, the method comprising forming the second semiconductor region by implantation of impurities of different conductivity types using an implantation acceleration energy with a projected range of 0.2 μm or more and 0.3 μm or less,
wherein a profile of the second semiconductor region is predominantly determined during formation of the insulating film.

While the disclosure has been shown and described in detail, the foregoing description is in all aspects illustrative and not restrictive. It is therefore understood that numerous modifications and variations can be devised.

1. A semiconductor device comprising:
a first semiconductor region;
a second semiconductor region provided on the first semiconductor region, at least a part of the second semiconductor region having an impurity concentration higher than an impurity concentration of the first semiconductor region;
an insulating film provided on the second semiconductor region; and
a conductive film provided on the second semiconductor region with the insulating film interposed between the conductive film and the second semiconductor region,
the second semiconductor region including
an upper region,
a middle region which is provided to be deeper than the upper region and has the impurity concentration higher than the impurity concentration in the upper region, and
a lower region which is provided to be deeper than the middle region, has the impurity concentration lower than the impurity concentration in the middle region, the impurity concentration in the lower region being constant at a depth of 0.5 μm or more.

2. The semiconductor device according to claim 1, wherein
the impurity concentration in an upper portion of the upper region is 1.0E17/cm³ or more and 1.0E19/cm³ or less,
the impurity concentration in the middle region has a peak higher than 1.0E19/cm³ at a depth of 0.2 μm or more and 0.3 μm or less from a lower surface of the insulating film, and
the impurity concentration in the lower region is less than 1.0E16/cm³ at a depth of 0.5 μm or more from the lower surface of the insulating film.

3. The semiconductor device according to claim 1, wherein
the impurity concentration in an upper portion of the upper region is 1.0E18/cm³ or more and 1.0E19/cm³ or less,
the impurity concentration in the middle region has a peak higher than 1.0E19/cm³ at a depth of 0.2 μm or more and 0.3 μm or less from a lower surface of the insulating film, and
the impurity concentration in the lower region is less than 1.0E16/cm³ at a depth of 0.5 μm or more from the lower surface of the insulating film.

4. The semiconductor device according to claim 1, wherein
the impurity concentration in an upper portion of the upper region is 1.0E17/cm³ or more and 1.0E19/cm³ or less,
the impurity concentration in the middle region has a plurality of peaks higher than 1.0E19/cm³ at a depth of 0.05 μm or more and less than 0.5 μm from a lower surface of the insulating film, and
the impurity concentration in the lower region is less than 1.0E16/cm³ at a depth of 0.5 μm or more from the lower surface of the insulating film.

5. The semiconductor device according to claim 1, wherein
the insulating film is provided on the second semiconductor region with the first semiconductor region interposed between the insulating film and the second semiconductor region, the first semiconductor region having the impurity concentration of less than 1.0E16/cm³,
the impurity concentration in an upper portion of the upper region is equal to or higher than the impurity concentration of the first semiconductor region,
the impurity concentration in the middle region has a peak higher than 1.0E19/cm³ at a depth of 0.2 μm or more and 0.3 μm or less from a lower surface of the insulating film, and
the impurity concentration in the lower region is less than 1.0E16/cm³ at a depth of 0.5 μm or more from the lower surface of the insulating film.

6. A method of manufacturing the semiconductor device according to claim 1, the method comprising forming the second semiconductor region by implantation of an impurity using an implantation acceleration energy with a projected range of 0.2 μm or more and 0.3 μm or less,
wherein a profile of the second semiconductor region is predominantly determined during formation of the insulating film.

7. A method of manufacturing the semiconductor device according to claim 1, the method comprising forming the second semiconductor region by implantation of an impurity having a smaller diffusion coefficient than phosphorus or boron,
wherein a profile of the second semiconductor region is predominantly determined during formation of the insulating film.

8. A method of manufacturing the semiconductor device according to claim 1, the method comprising forming the second semiconductor region by implantation of an impurity having a smaller diffusion coefficient than phosphorus or boron using an implantation acceleration energy with a projected range of 0.2 μm or more and 0.3 μm or less,
wherein a profile of the second semiconductor region is predominantly determined during formation of the insulating film.

9. A method of manufacturing the semiconductor device according to claim 1, the method comprising forming the second semiconductor region by implantation of an impurity using different implantation acceleration energies with a projected range of 0.2 μm or more and 0.3 μm or less,
wherein a profile of the second semiconductor region is predominantly determined during formation of the insulating film.

10. A method of manufacturing the semiconductor device according to claim 1, the method comprising forming the second semiconductor region by implantation of impurities of different conductivity types using an implantation acceleration energy with a projected range of 0.2 μm or more and 0.3 μm or less.
wherein a profile of the second semiconductor region is predominantly determined during formation of the insulating film.
